(19) United States
(12) Patent Application Publication
(10) Pub. No.: US 2005/0195983 A1
(43) Pub. Date: Sep. 8, 2005

(54) METHOD OF ANALOG MATH PROCESSING FOR CONTROLLED DISTORTION OF AN ELECTRIC AUDIO SIGNAL AND DEVICE

(76) Inventor: ILITCH CHILIACHKI, Santa Barbara, CA (US)

Correspondence Address: Mr.ILITCH S CHILIACHKI, 2517 Modoc Road Apt #28, Santa Barbara, CA, 93105-4158, US

(21) Appl. No.: 10/906,644

(22) Filed: Feb. 28, 2005

Related U.S. Application Data
(60) Provisional application No. 60/521,173, filed on Mar. 3, 2004.

(51) Int. Cl. H03G 3/00; H03F 21/00

(52) U.S. Cl. 381/61; 381/120

(57) ABSTRACT

This invention is relating to an active, all analog electronic device, for performing a controlled distortion processing over an electric audio signal applied to its input. As a result an output electric audio signal, corresponding to the input electric audio signal is produced. The output electric audio signal is distorted, and contains the dynamics, harmonics, phase shifting and time relations between the components of the input signal. The Method of Analog Math Processing for Controlled Distortion of an electric audio signal and Device consists gain, gain controlling, signal attenuating, buffering and summing stages, blending, tone and level variable controls. The summing stages are arranged to receive signal portions from the gain stages, through their corresponding attenuating stages. These signal portions are summed, based on the analog math processing principles and a distorted electric audio signal is produced with a wide range of smooth and controlled overdrive and distortion effect.

### BACKGROUND OF THE INVENTION

1. Field of the Invention

This invention pertains to the field of electronic pre-amplifying devices used to modify the harmonic characteristics of an electric audio signal. Electric and electronic musical instruments or vocal microphones usually produce an electric audio signal.

2. Description of the Prior Art

There are several conventional methods for overdriving and distorting of an electric audio signal. They use either High gain, voltage clipping amplifying stages, or Diodes clipping circuits, or Diodes rectifying circuits, or Feedback loop diodes, or Digital signal processing and so on. In most of these applications there is either a partial or almost total lost of most or some of the main tonal characteristic components of the electric audio signal such as: dynamics, harmonic components, phase shifting, time relations between the signal components etc.

### SUMMARY OF THE INVENTION

In view of the foregoing disadvantages inherent in the known types of Distortion and Overdrive sound effects, the present invention provides a new Method of Analog Math Processing for Controlled Distortion of an electric audio signal and Device. If an electric audio signal is connected to the input of the Device, a distorted output electric audio signal with smooth and controlled distortion parameters is produced. The main advantage of the present invention is that it provides an overdriven and distorted output signal that contains the dynamics, frequencies, harmonics, phase shifting and signal components time relations, that are presented in the original input electric audio signal.

Another advantage of the present invention is that the output signal produced is still distorted if a low level of the input signals, enters the input of the Device.

### BRIEF DESCRIPTION OF THE DRAWINGS

The Method of Analog Math Processing for Controlled Distortion of an electric audio signal and Device invention, will be better understood considering the following drawing and waveform graphic sets (not to be used for scaling), which are:

FIG. 1 illustrates a Block Diagram of the Method of Analog Math Processing for Controlled Distortion of an electric audio signal and Device.

FIG. 2 illustrates a set of Input and Output waveform graphics. A low level (about 30 mVp (peak)) electric audio signal (1000 Hz sine view) is generated by the Signal Source (1). The Main Blending control device (19) is at its minimum position (DYNA mode).

FIG. 3 illustrates a set of Input and Output waveform graphics. A low level (about 30 mVp) electric audio signal (1000 Hz sine view) is generated by the Signal Source (1). The Main Blending control device (19) is at its maximum position (DIST mode).

FIG. 4 illustrates a set of Input and Output waveform graphic. A high level (about 600 mVp) electric audio signal (1000 Hz sine view) is generated by the Signal Source (1). The Main Blending control device (19) is at its minimum position (DYNA mode).

FIG. 5 illustrates a set of Input and Output waveform graphics. A high level (about 600 mVp) electric audio signal (1000 Hz sine view) is generated by the Signal Source (1). The Main Blending control device (19) is at its maximum position (DIST mode).

### DETAILED DESCRIPTION

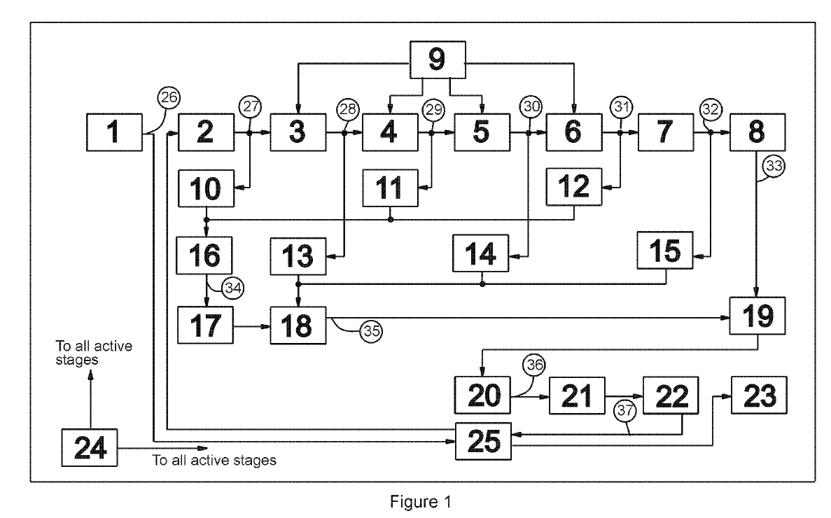

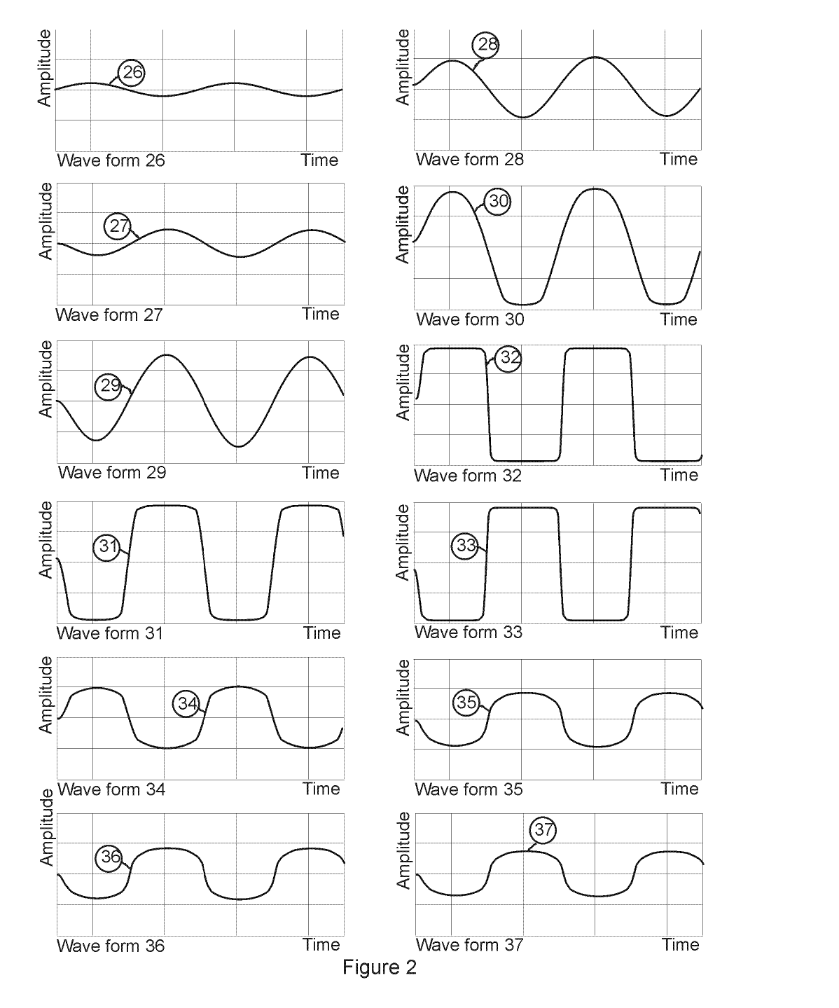

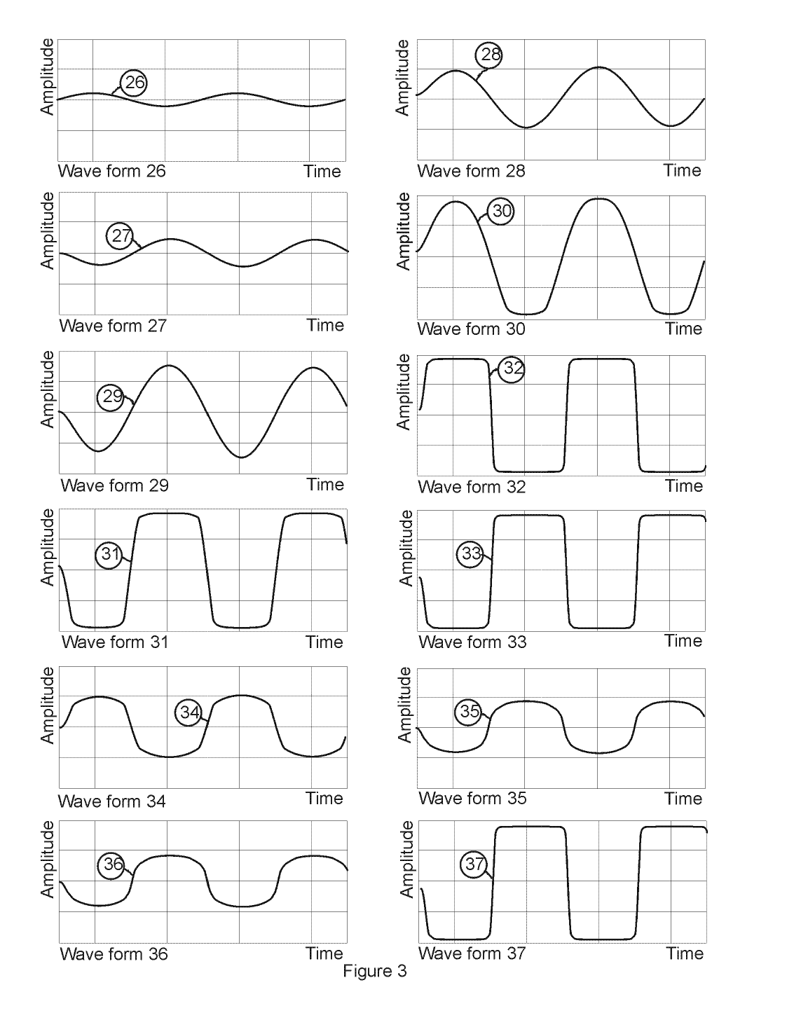

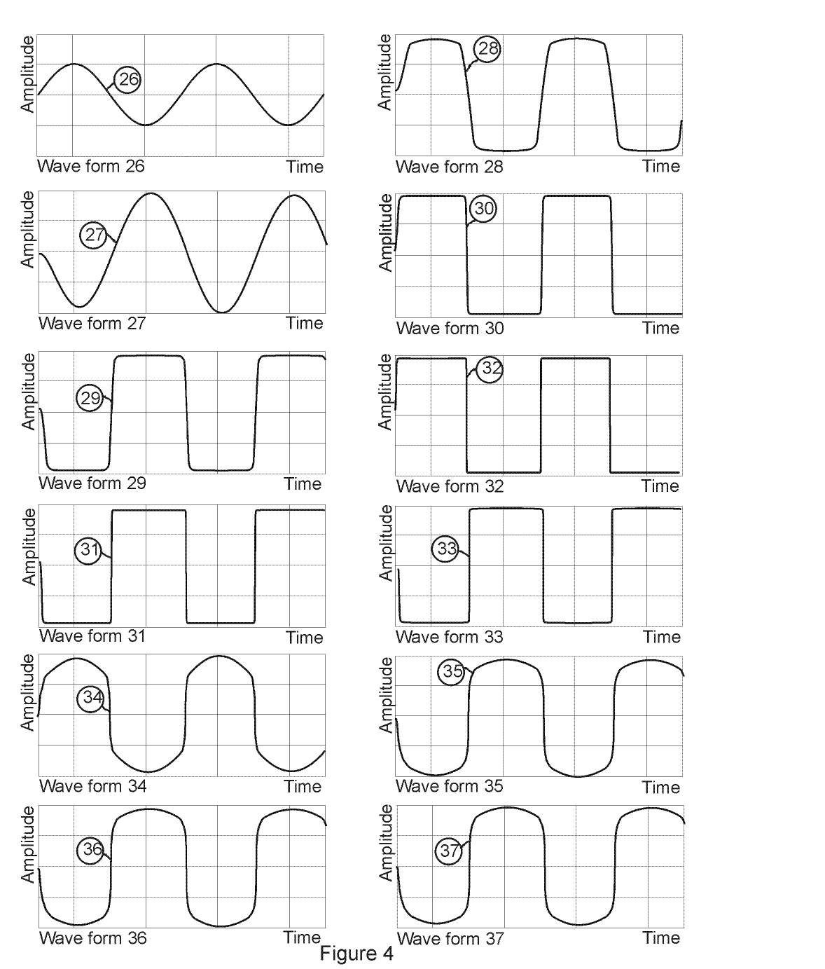

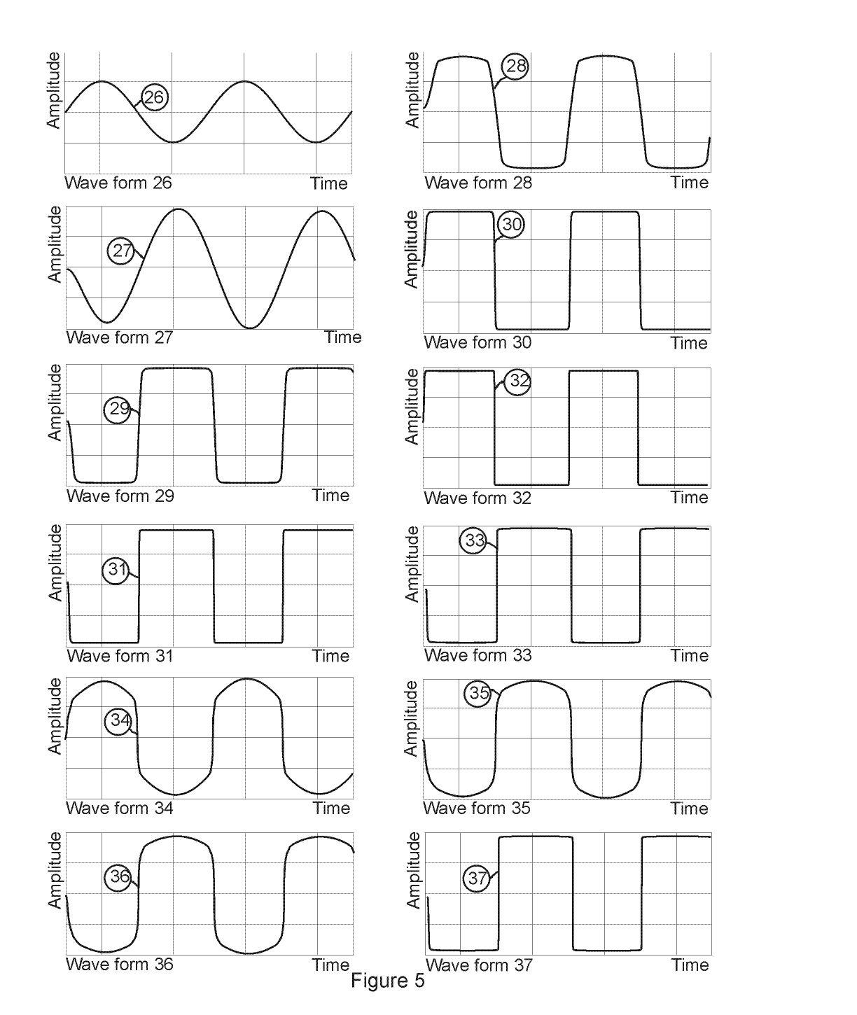

With reference now to the drawings, and in particular to FIG. 1, FIG. 2 FIG. 3, FIG. 4 and FIG. 5 thereof, a new Method of Analog Math Processing for Controlled Distortion of an electric audio signal and Device invention, will be described. The example will be explored with 6 (six), in series connected, gain stages used. The particular number of gain stages used is not a limit for the invention.

FIG. 1 illustrates a functional Block Diagram of a preferred embodiment of the Method of Analog Math Processing for Controlled Distortion of an electric audio signal and Device. It consists of the following blocks and waveform test points:

1. Electric audio signal source.

2. First gain stage.

3. Second gain stage.

4. Third gain stage.

5. Fourth gain stage.

6. Fifth gain stage.

7. Sixth gain stage.

8. Inverting buffer stage (for DIST Mode).

9. Gain control device (Drive).

10. Attenuating stage for the signal from the output of the First gain stage.

11. Attenuating stage for the signal from the output of the Third gain stage.

12. Attenuating stage for the signal from the output of the Fifth gain stage.

13. Attenuating stage for the signal from the output of the Second gain stage.

14. Attenuating stage for the signal from the output of the Fourth gain stage.

15. Attenuating stage for the signal from the output of the Sixth gain stage.

16. Inverted phase signals, summing stage.

17. Attenuating Stage for the signal from the output of the Inverted phase signals summing stage.

18. Non-Inverted phase signals, summing stage.

19. Main blending control device (DYNA DIST control).

20. Blending and output amplifying stage.

21. Tone control stage (Tone).

22. Output volume control device (Level).

23. Electric audio signal receiver (Audio Amplifier).

24. Main Power supply.

25. ON/OFF foot switch and Light indicator stage.

26. Waveform graphic at the Electric audio signal source output.

27. Waveform graphic at the First gain stage output.

28. Waveform graphic at the Second gain stage output.

29. Waveform graphic at the Third gain stage output.

30. Waveform graphic at the Fourth gain stage output.

31. Waveform graphic at the Fifth gain stage output.

32. Waveform graphic at the Sixth gain stage output.

33. Waveform graphic at the Inverting buffer stage output.

34. Waveform graphic at the Inverted signals summing stage output.

35. Waveform graphic at the Non-Inverted signals summing stage output.

36. Waveform graphic at the Blending and output amplifying stage output.

37. Waveform graphic at the Output volume control device output.

In General:

The Main Power supply (24) provides DC electrical power to all active stages of the device. In the preferred embodiment an internal circuit is provided to secure a low DC Voltage powering for the Second, Third, Fourth, Fifth and Sixth gain stages. Thus, the voltage clipping in these stages happens, when the passing through electric audio signal reaches the voltage rails of the low DC Voltage power supply.

All gain stages (2, 3, 4, 5, 6, 7), buffer stage (8) and Summing stages (16, 18) invert their input signals by 180 degree (they are phase Inverting stages).

The Blending and output amplifying stage (20), is a Non-inverting stage.

For the waveform graphic sets presented on FIG. 2 through FIG. 5 the Gain control device (9) (DRIVE) is positioned at its maximum position.

The Electric audio signal source (1) produces an electric audio signal—Waveform graphic (26), with particular amplitude and frequency band range. The preferred embodiment, presented, is designed for a standard 6-strings electric guitar, which produces maximum AC voltage amplitude of about 600 mVp(peak) and frequency band range from about 40 Hz up to 10 kHz. The First gain stage (2) provides a high Input impedance, so the Electric audio signal source (1) does not meet any significant loading.

The ON/OFF foot switch and Light indicator stage (25)—which is a true bypass foot switch, at its OFF position, connects direct the signal (26) coming out from the Electric audio signal source (1) to the Electric audio signal receiver (Audio Amplifier) (23). The ON/OFF foot switch and Light indicator stage (25), at its ON position, connects the signal (26) coming out from the Electric audio signal source (1) to the input of the First gain stage (2). The First gain stage (2) has a determined amount of gain bigger than 1 (one) and smaller than, but not limited to 5 (five) times. In the presented embodiment, the gain of the First gain stage is set to approximately 4 (four) times. The signal output of the First gain stage (2), enters the input of the Second gain stage (3). The gain of the Second gain stage (3) is variable from 1 (one) to 3 (three) times and is controlled by the Gain control device (9). The signal output of the Second gain stage (3) enters the input of the Third gain stage (4). The gain of the Third gain stage (4) is variable from 1 (one) to 3 (three) times and is controlled by the Gain control device (9). The signal output of the Third gain stage (4) enters the input of the Fourth gain stage (5). The gain of the Fourth gain stage (5) is variable from 1 (one) to 3 (three) times and is controlled by the Gain control device (9). The signal output of the Fourth gain stage (5) enters the input of the Fifth gain stage (6). The gain of the Fifth gain stage (6) is variable from 1 (one) to 3 (three) times and is controlled by the Gain control device (9). The signal output of the Fifth gain stage (6) enters the input of the Sixth gain stage (7). The gain of the Sixth gain stage (7) is fixed, but not limited to 3 (three) times. The Attenuating stages (10), (11) and (12) receive on their inputs the corresponding output signals from First, Third and Fifth gain stages (2, 4 and 6), which are in signal phase agreement. The Attenuating stages (10), (11) and (12) determine the amount of signals to be summed by the Inverted phase signals summing stage (16). The Attenuating stages (13), (14), (15) and (17) receive on their inputs the corresponding output signals from Second, Fourth and Sixth gain stages (3, 5 and 7) and the Inverted phase signals summing stage (16), which are in signal phase agreement. The Attenuating stages (13, 14, 15 and 17) determine the amount of signals to be summed by the Non-Inverted phase signals summing stage (18). The Inverting buffer stage (8) buffers and inverts the phase of the signal coming out from the output of the Sixth gain stage (7) and provides a signal (33) on its output with amplitude and phase agreement with the output signal (35) coming out from the Non-inverted phase signals summing stage (18). The two signals (33) and (35) are connected to the two shoulders of the Main Blending control device (19) (DYNA DIST control). In the preferred embodiment the Main Blending control device (19) is a passive, linear variable resistor (potentiometer) 100 Kohms/B. At its Minimum position only the signal (35) is blended to the next Blending and output amplifying stage (20). At its Maximum position, only the signal (33) is blended to the next Blending and output amplifying stage (20). For any position in-between the Minimum and Maximum positions of (19), particular portions from both signals (35) and (33) are blended to the Blending and output amplifying stage (20). The Blending and output amplifying stage (20) secures low output impedance and capacity to drive 5 Kohms impedance load. The Tone control stage (21) is a tone shaping circuit for adjusting the tonal characteristics of the signal coming out from the Blending and output amplifying stage (20). The Output volume control device (22) is a signal level controlling circuit for adjusting the level of the signal (37) coming out from the entire Device. The ON/OFF foot switch and Light indicator stage (35) connects the electric audio signal (26) from the Signal source (1) directly to the Audio amplifier (23) at its OFF position. The ON/OFF foot switch and Light indicator stage (35) at its ON position, connects the electric audio signal (26) from the Signal source (1) to the input of the First gain stage (2) and the signal from the Output volume control device (22) to the Audio Amplifier (23).

Now, with reference to the Waveform graphic sets in FIG. 2, FIG. 3, FIG. 4 and FIG. 5 their detailed explanation is provided.

The Waveform graphic (26) is a Non-inverted phase signal at the output of the Electric audio signal source (1). The Waveform graphic (27) is an inverted phase signal at the output of the First gain stage (2). The Waveform graphic (28) is a Non-inverted phase signal at the output of the Second gain stage (3). The Waveform graphic (29) is an inverted phase signal at the output of the Third gain stage (4). The Waveform graphic (30) is a Non-inverted phase signal at the output of the Forth gain stage (5). The Waveform graphic (32) is an inverted phase signal at the output of the Fifth gain stage (6). The Waveform graphic (32) is a Non-inverted phase signal at the output of the Sixth gain stage (7). The Waveform graphic (33) is a Non-inverted phase signal from at the output of the Inverting buffer stage (8). The Waveform graphic (34) is a Non-inverted phase signal at the output of the summing stage (16). The Waveform graphic (35) is an inverted phase signal at the output of the summing stage (18). The Waveform graphic (36) is an inverted phase signal at the output of the Blending and output amplifying stage (20). The Waveform graphic (37) is an inverted phase signal at the output of the Output volume control device (22).

On FIG. 2—The Waveform graphic (37) is the final output signal produced by the device. The Gain control device (9) is positioned at its maximum position. The Main blending control device (19) is located at its Minimum position and the signal from the Electric audio signal source (1) connected, is with amplitude of 30 mVp.

On FIG. 3—The Waveform graphic (37) is the final output signal produced by the device. The Gain control device (9) is positioned at its maximum position. The Main blending control device (19) is located at its Maximum position and the signal from the Electric audio signal source (1) connected, is with amplitude of 30 mVp.

On FIG. 4—The Waveform graphic (37) is the final output signal produced by the device. The Gain control device (9) is positioned at its maximum position. The Main blending control device (19) is located at its Minimum position and the signal from the Electric audio signal source (1) connected, is with amplitude of 600 mVp.

On FIG. 5—The Waveform graphic (37) is the final output signal produced by the device. The Gain control device (9) is positioned at its maximum position. The Main blending control device (19) is located at its Maximum position and the signal from the Electric audio signal source (1) connected, is with amplitude of 600 mVp.

It should be noted, that summing and blending of equal or different portions of signal from each output of the multiple gain stages could also obtain various combinations and original types of distortion. The only requirement when summing the signals, is that the summed signals must have the same phase orientation (signals phase agreement). This is to avoid any undesirable signal cancellations and phase disordering of the original electric audio signal. These new types of distortion should be considered as hybrids of the type presented with this invention.

The above description disclosed, the drawings and waveforms attached, clearly describe the Method of Analog Math Processing for Controlled Distortion of an electric audio signal and Device. Those skilled in the art, based on this disclosure, drawings and waveform graphics could make variations and modifications to the instant invention. Therefore, this invention is not to be limited by the disclosure, drawings and waveforms presented, but by the claims listed.

1. Method of Analog Math Processing for Controlled Distortion of an electric audio signal and Device for introducing controlled distortion to an electric audio signal, thereof comprising:
a fixed gain semiconductor amplifying stage said First gain stage, having predetermined high input impedance and frequency response, to form the amplitude and frequency band of the electric audio signal passing through the entire device;
a variable gain semiconductor amplifying stage said Second gain stage, having predetermined minimum and maximum variable gain;
a variable gain semiconductor amplifying stage said Third gain stage, having predetermined minimum and maximum variable gain;
a variable gain semiconductor amplifying stage said Fourth gain stage, having predetermined minimum and maximum variable gain;
a variable gain semiconductor amplifying stage said Fifth gain stage, having predetermined minimum and maximum variable gain;
a fixed gain semiconductor amplifying stage said Sixth gain stage, having predetermined consistent amount of gain.

2. The Method of Analog Math Processing for Controlled Distortion of an electric audio signal and Device of claim 1 in which said Attenuating stages, corresponding to the First, Second, Third, Fourth, Fifth and Sixth gain stages, determine the amount of signal from the corresponding gain stages outputs to be summed.

3. A multiple gain control circuit said Gain control device (DRIVE), simultaneously varies the amount of amplification of said Second gain stage, Third gain stage, Fourth gain stage and Fifth gain stage.

4. A blending control circuit said Main blending control device (DYNA DIST control), blends and mixes the output signals coming out from said Non-inverted phase signals summing stage and said Inverting buffer stage Distortion Mode.
